(19) United States
(12) Patent Application Publication
(10) Pub. No.: US 2025/0297766 A1
(43) Pub. Date: Sep. 25, 2025

(54) Electric Control Box and Air Conditioner

(71) Applicant: GD MIDEA AIR-CONDITIONING EQUIPMENT CO., LTD., Foshan (CN)

(72) Inventors: Yong ZENG, Foshan (CN); Jianping LING, Foshan (CN); Zhicheng ZHAO, Foshan (CN); Zixi LI, Foshan (CN)

(21) Appl. No.: 18/863,438

(22) PCT Filed: Jun. 14, 2023
(86) PCT No.: PCT/CN2023/100220

§ 371 Date: Nov. 6, 2024

(30) Foreign Application Priority Data
Jun. 29, 2022 (CN) 202210761977.X

(51) Int. Cl. F24F 11/89

(52) U.S. Cl. CPC F24F 11/89

(57) ABSTRACT

An electric control box and an air conditioner. The electric control box comprises an electric-control-box cover (2) and an electric-control-box body (1), wherein the bottom of the electric-control-box body (1) is provided with an opening mouth (27), and the electric-control-box cover (2) is configured to cover the opening mouth (27); and the bottom of the electric-control-box body (1) is provided with a socket (23), the opening of the socket (23) is configured to face an inside of the opening mouth (27), a portion of an edge of the electric-control-box cover (2) is inserted into the socket (23), and an opening wall of the socket (23) is configured for positioning the electric-control-box cover (2), so that the electric-control-box cover (2) is maintained in a cantilevered state. The air conditioner comprises a ceiling-mounted air conditioner indoor unit and an electric control box, the electric control box being arranged in the air conditioner indoor unit.

### TECHNICAL FIELD

The present disclosure relates to, but is not limited to, the field of household appliances, and particularly relates to an electric control box and an air conditioner.

### BACKGROUND

At present, there are two main connection manners between the electric-control-box cover and the electric-control-box body of the related ceiling-mounted air conditioner indoor unit: the first one is to fasten by four screws, and the second one is to fasten by two screws on one side and use a pin structure on the other side. However, the above connection manners have the following problems in the installation or maintenance process: when four screws are used for fastening, since it is an upward operation, the installer needs to hold the electric-control-box cover with his hand during the installation process to prevent the electric-control-box cover from falling, and damaging or injuring people. When adopting the connection manner with two screws and the pin, although the problem that the electric-control-box cover falls off can be solved, the manufacturing cost will be increased, and the pin needs to be additionally manufactured and connected with the electric-control-box cover by welding or the like, thus improving the manufacturing complexity.

### SUMMARY

The following is a summary of the subject matter described in detail herein. This summary is not intended to limit the protection scope of the claims.

At least one embodiment of the present disclosure provides an electric control box, including an electric-control-box cover and an electric-control-box body, wherein a bottom of the electric-control-box body is provided with an opening mouth, and the electric-control-box cover is configured to cover the opening mouth; a bottom of the electric-control-box body is provided with a socket, an opening of the socket is configured to face an inside of the opening mouth, a portion of an edge of the electric-control-box cover is inserted into the socket, and an opening wall of the socket is configured for positioning the electric-control-box cover, so that the electric-control-box cover is maintained in a cantilevered state.

At least one embodiment of the present disclosure provides an air conditioner, including a ceiling-mounted air conditioner indoor unit and the electric control box described above, the electric control box being arranged within the air conditioner indoor unit.

Other aspects will become apparent after reading and understanding the drawings and detailed description.

### BRIEF DESCRIPTION OF DRAWINGS

FIG. 1 is a schematic diagram of an electric control box according to an embodiment of the present disclosure.

FIG. 2 is a schematic side view of the electric control box in FIG. 1.

FIG. 3 is a schematic exploded view of the electric control box in FIG. 1.

FIG. 4 is a partially enlarged schematic view of part A in FIG. 2.

FIG. 5 is a schematic diagram of the box main body in FIG. 3.

FIG. 6 is a schematic diagram of the electric-control-box body in FIG. 1.

FIG. 7 is a partially enlarged schematic view of part B in FIG. 6.

FIG. 8 is a side view of the mounting box in FIG. 3.

FIG. 9 is a schematic diagram of the mounting box in FIG. 3.

FIG. 10 is a schematic three-dimensional view of the electric-control-box body in FIG. 1.

FIG. 11 is a schematic diagram of the wiring base board in FIG. 3.

FIG. 12 is a schematic diagram of a connection between the wiring base board and the electric control main board in FIG. 3.

### DESCRIPTION OF REFERENCE SIGNS

1—electric-control-box body, 2—electric-control-box cover, 3—box main body, 4—limit member, 5—air-switch module, 6—shell, 7—air switch, 8—mounting box, 9—mounting cover, 10—first edge, 11—second edge, 12—first fixation hole, 13—buckle, 14—wiring base board, 15—electric control main board, 16—sidewall, 17—first sidewall, 18—second sidewall, 19—third sidewall, 20—fourth sidewall, 21—top plate, 22—operation window, 23—socket, 24—flange, 25—support section, 26—inclined section, 27—opening mouth, 28—bottom rim, 29—mounting hole, 30—notch, 31—second fixation hole, 32—extension plate, 33—first folding edge, 34—second folding edge, 35—hemming edge, 36—positioning pin, 37—positioning hole, 38—third fixation hole, 39—fourth fixation hole, 40—reinforcement rib, 41—fifth fixation hole, 42—limiting buckle, 43—sixth fixation hole, 44—mounting base, 45—third edge, 46—fourth edge, 47—opening, 48—positioning groove.

### DETAILED DESCRIPTION

Hereinafter, embodiments of the present disclosure will be described in detail with reference to the accompanying drawings. It should be noted that, the embodiments of the present disclosure and the features in the embodiments may be arbitrarily combined with each other if there is no conflict.

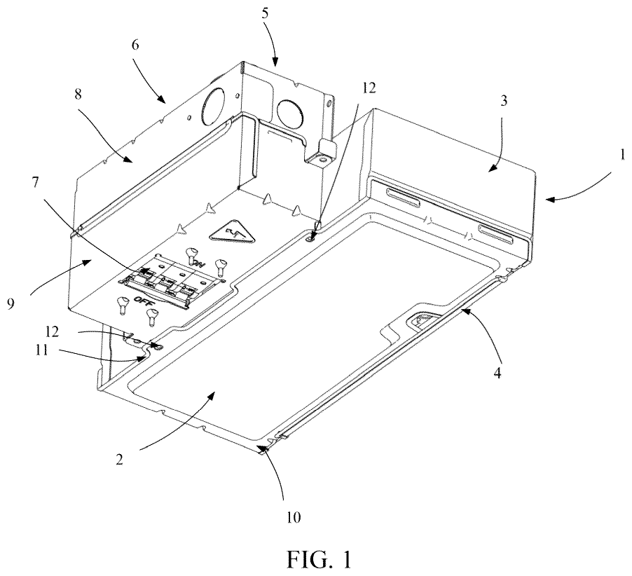

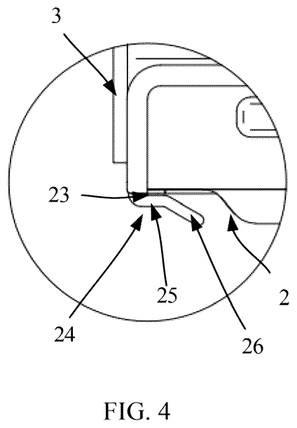

Referring to FIGS. 1, 4, and 5, the electric control box according to an embodiment of the present disclosure can be used in an air conditioner indoor unit, and the air conditioner indoor unit may be an air conditioner indoor unit fixed on a ceiling. The electric control box includes an electric-control-box body 1 and an electric-control-box cover 2, the electric-control-box body 1 and the electric-control-box cover 2 are detachably connected. An opening mouth 27 of the electric-control-box body 1 is located at the bottom of the electric-control-box body 1 due to the installation position of the air conditioner indoor unit, and the electric-control-box cover 2 can cover the opening mouth 27 to seal and protect an electric control main board in the electric control box and ensure electricity safety, waterproof and dustproof. The bottom of the electric-control-box body 1 is provided with a socket 23, and an opening 47 of the socket 23 faces an inside of the opening mouth 27. In order to prevent the electric-control-box cover 2 from falling off, an edge of the electric-control-box cover 2 can be inserted into the socket 23 through the opening 47 to form an inserting connection between the electric-control-box cover 2 and the socket 23, whereby a sidewall (i.e. the opening wall) of the socket 23 can abut against the electric-control-box cover 2 to form a positioning, such that the electric-control-box cover 2 is in a cantilevered state without other connections. The socket 23 can be fitted with the edge of the electric-control-box cover 2 to prevent the electric-control-box cover 2 from falling, which can ensure that the electric-control-box cover 2 does not need to be held by a person with his hand and does not directly fall, thereby improving the safety and efficiency of installation and maintenance.

Also as shown in FIGS. 1, 4 and 5, the electric-control-box body 1 includes a box main body 3 for placing the electric control main board, and a limit member 4 connected to the box main body 3, the opening mouth 27 is at the bottom of the box main body 3, the bottom of the box main body 3 forms a bottom rim 28, and the bottom rim 28 is arranged around the opening mouth 27. The limit member 4 is arranged along an extension direction of the bottom rim 28, and the limit member 4 extends downward so that the limit member 4 can protrude from the bottom rim 28. One end of the limit member 4 extends toward a center of the opening mouth 27 so that there is a gap between the bottom rim 28 and the limit member 4, the gap encloses and forms the socket 23. An end face of the limit member 4 facing the bottom rim 28 and an end face of the bottom rim 28 facing the limit member 4 constitute the opening wall of the socket 23.

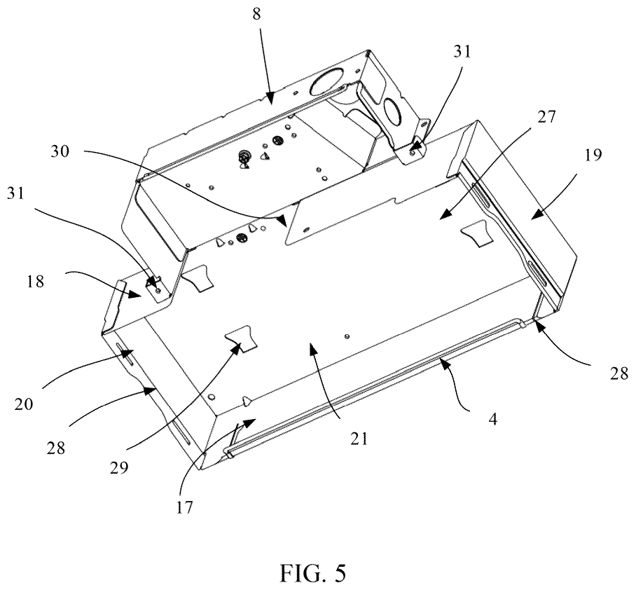

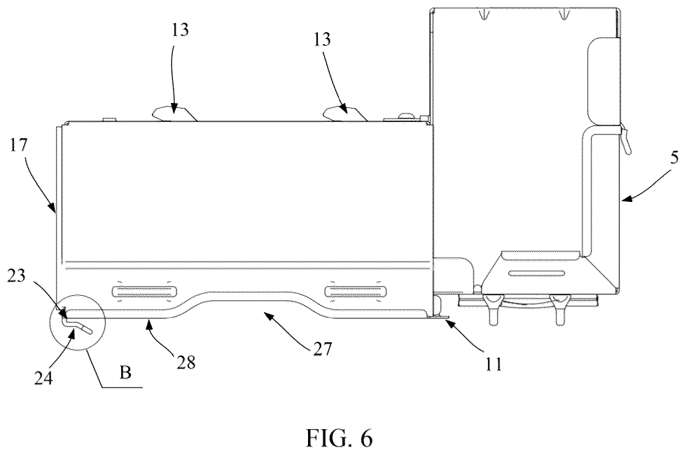

As shown in FIGS. 5, 6 and 7, the box main body 3 is a metal member, the box main body 3 is a rectangular box-like structure with one opened side, the box main body 3 includes four sidewalls 16 forming a rectangular ring, the four sidewalls 16 include a first sidewall 17, a second sidewall 18, a third sidewall 19, and a fourth sidewall 20. The first sidewall 17, the third sidewall 19, the second sidewall 18, and the fourth sidewall 20 are connected end to end in sequence. The first sidewall 17, the second sidewall 18, the third sidewall 19, and the fourth sidewall 20 form a rectangular ring, one end of the rectangular ring forms a rectangular opening mouth 27, the other end of the rectangular ring is connected with a rectangular top plate 21 matched with the rectangular ring, so as to close the side of the rectangular ring. End surfaces of the first sidewall 17, the second sidewall 18, the third sidewall 19, and the fourth sidewall 20 facing away from the top plate 21 form the bottom rim 28. The structure of the box main body 3 is not limited thereto, and the box main body 3 may have, for example, a circular box shape, a diamond box shape, or the like. The wiring base board 14 and the electric control main board 15 can be installed in the box main body 3, and the wiring base board 14 and the electric control main board 15 can be fixed to the top plate 21.

As also shown in FIGS. 5, 6 and 7, the limit member 4 may also be a metal member, the limit member 4 is processed synchronously with the box main body 3, and the integrated structure can improve the processing efficiency. When producing the box main body 3, the limit member 4 can be formed by bending the excess material by the processing personnel when the sidewall 16 is formed by punching and bending. The limit member 4 is located on the first sidewall 17, that is, the limit member 4 is located at an end of the first sidewall 17 away from the top plate 21, and the limit member 4 can be formed by further bending the sheet material from which the first sidewall 17 is processed. The position of the limit member 4 is not limited thereto. For example, the limit member 4 may be located on the third sidewall 19 or the fourth sidewall 20, or for example, the first sidewall 17 and the third sidewall 19 may each provided with the limit member 4. The limit member 4 may be located on a plurality of sidewalls 16 or on one sidewall 16. Specifically, the limit member 4 includes an extension plate 32 and a flange 24, the extension plate 32 extends vertically, the flange 24 is bent to one side. The extension plate 32 extends downward, extension directions of the extension plate 32 and the first sidewall 17 are consistent. The flange 24 is at a lower end of the extension plate 32, the flange 24 extends towards a center of the opening mouth 27, which can also be understood as extending toward the opposite sidewall 16 (i.e. the second sidewall 18), the flange 24 is spaced apart from the bottom rim 28 to form the socket 23 described above.

As shown in FIGS. 1, 2 and 4, the electric-control-box cover 2 is a sheet metal stamping part, and the structure of the electric-control-box cover 2 is simple. The shape of the electric-control-box cover 2 is adapted to the box main body 3, the electric-control-box cover 2 is rectangular. Peripheral edges of the electric-control-box cover 2 include a first edge 10, a second edge 11, a third edge 45 and a fourth edge 46. The first edge 10, the second edge 11, the third edge 45 and the fourth edge 46 are respectively adapted to bottom surfaces of the first sidewall 17, the second sidewall 18, the third sidewall 19 and the fourth sidewall 20, so as to ensure the sealing between the electric-control-box cover 2 and the box main body 3. A portion of the first edge 10 is located within the socket 23, which can limit the side of the electric-control-box cover 2. A thickness of the electric-control-box cover 2 at the position of the first edge 10 is to, and the second edge 11 is provided with two first fixation holes 12 for connecting to the box main body 3 by screws. The first fixation hole 12 is not limited to be located on the second edge 11, for example, the first fixation hole 12 may be located on the third edge 45 or the fourth edge 46.

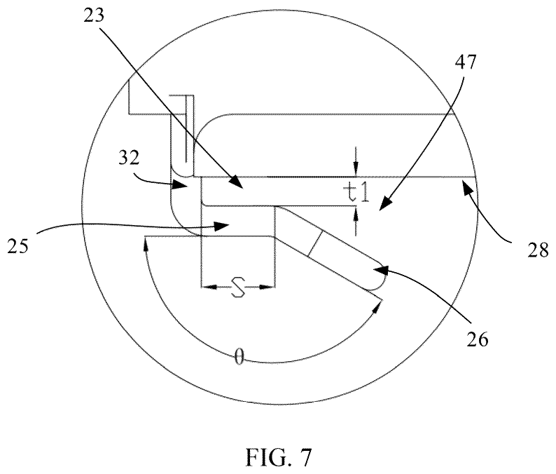

In some exemplary embodiments, as shown in FIG. 7, the flange 24 is divided into two connected parts, i.e., a support section 25 extending horizontally and an inclined section 26 obliquely arranged. The support section 25 is perpendicular to the extension plate 32 and configured to be connected to the extension plate 32. The inclined section 26 is inclined downward so that the opening degree of the opening 47 is relatively large, and the inclined section 26 can guide the first edge 10 for insertion, and can also facilitate the removal of the first edge 10. In some exemplary embodiments, the width of the socket 23, that is, a spacing between the support section 25 and the bottom rim 28, is set to ti, where t₀≤t₁≤1.2×t₀, t₀ is a thickness of the electric-control-box cover 2 at the position of the first edge 10, and a length of the support section 25 is s, where s≥2×t1. The above dimensional relationship can ensure that the cantilevered state is formed, and the electric-control-box cover 2 is not easily removed from the socket 23. In some exemplary embodiments, an included angle between the inclined section 26 and the first sidewall 17 is 90° to 120°, and this angular relationship may also be expressed as an included angle (i.e., θ) between the support section 25 and the inclined section 26 being between 150° and 180°. In this example, the angle between the inclined section 26 and the first sidewall 17 is 120°.

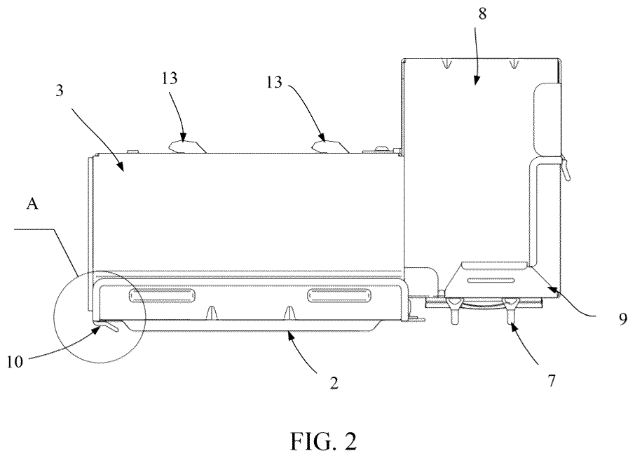

As shown in FIGS. 2, 5, 9 and 10, the wiring base board 14 is configured to be connected with the top plate 21, the electric control main board 15 is fixed on the wiring base board 14. A side of the wiring base board 14 facing the top plate 21 is provided with a protruding buckle 13, a plurality of buckles 13 are provided, and the shapes and sizes of the plurality of buckles 13 are consistent. The buckles 13 are hook-shaped, the top plate 21 is provided with mounting holes 29, the number of the mounting holes 29 is configured to be consistent with the number of buckles 13, and the mounting holes 29 correspond to the buckles 13 one-to-one. The mounting hole 29 is a trapezoidal hole, and the narrow side of the trapezoidal hole is equal to the width of the buckle 13, so that the mounting hole 29 can position the buckle 13 with clearance fit to prevent the buckle 13 from shaking or removing. When the wiring base board 14 is connected to the top plate 21, the buckle 13 can penetrate the mounting hole 29, the buckle 13 extends to a side of the top plate 21 facing away from the wiring base board 14, and an engagement is formed between the buckle 13 and an edge portion of the mounting hole 29, thereby fixing the wiring base board 14 with respect to the box main body 3. As a result, the plurality of buckles 13 and the plurality of mounting holes 29 cooperate to form a plurality of buckle structures, so as to accurately position the mounting position of the wiring base board 14. The wiring base board 14 is provided with a fifth fixation hole 41, and the top plate 21 is provided with a sixth fixation hole 43, and the fifth fixation hole 41 and the sixth fixation hole 43 correspond to each other, and the wiring base board 14 and the top plate 2 can be further fixed by a screw penetrating through the wiring base board 14 and the top plate 2. The wiring base board 14 and the box main body 3 can be fastened by only one screw, which can reduce the number of screws, avoid frequent operation of screws during installation or disassembly, facilitate the installation of the wiring base board 14, and greatly improve the production efficiency.

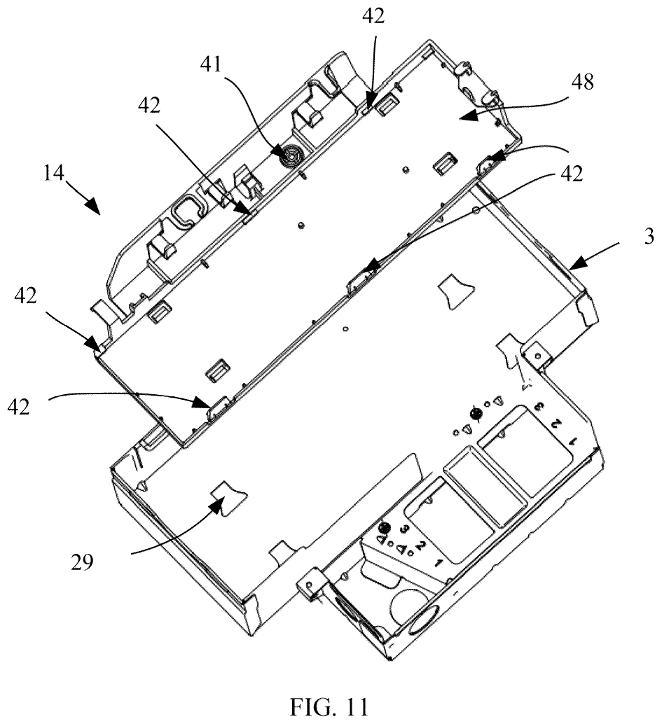

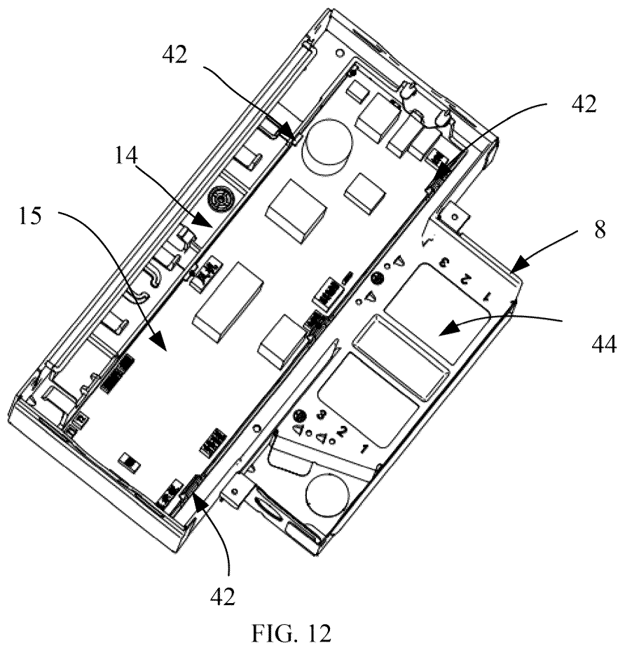

Also as shown in FIGS. 11 and 12, the electric control main board 15 is located on a side of the wiring base board 14 facing away from the top plate 21. A side of the wiring base board 14 facing away from the top plate 21 has a recessed positioning groove 48, the electric control main board 15 can be installed in the positioning groove 48. A plurality of limiting buckles 42 is provided at a groove opening of the positioning groove 48, and the plurality of limiting buckles 42 are evenly arranged along a peripheral direction of the groove opening of the positioning groove 48, and buckled on the edge of the electric control main board 15, thereby limiting the electric control main board 15.

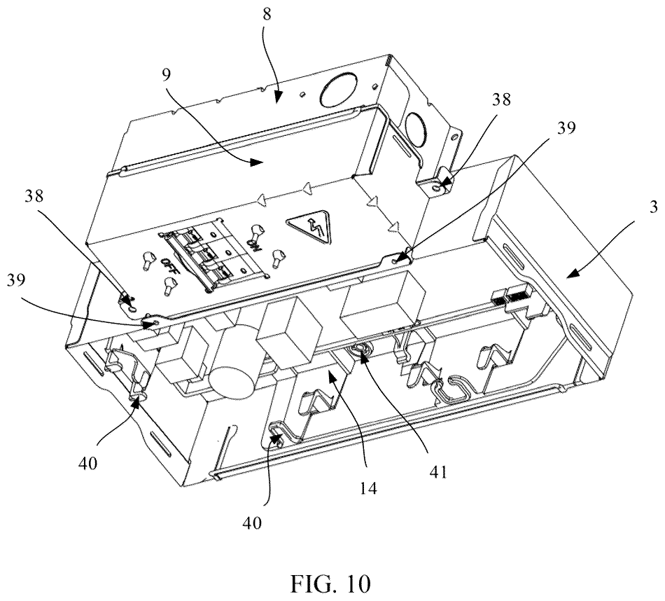

In some exemplary embodiments, as shown in FIG. 10, the wiring base board 14 is provided with a plurality of reinforcement ribs 40, and the reinforcement ribs 40 extend along the sidewall 16 to the opening mouth 27. The reinforcement ribs 40 can abut against the electric-control-box cover 2 to improve the strength of the electric control box and avoid deformation of the electric-control-box cover 2 after being pressed. In some exemplary embodiments, the reinforcement ribs 40 may extend along the first sidewall 17.

In some exemplary embodiments, one end of the second sidewall 18 away from the top plate 21 is provided with two threaded holes (not shown in the figures). The threaded holes correspond to the positions of the first fixation holes 12 and can be fastened by screws, and the box main body 3 forms fixation members at the positions of the threaded holes, whereby one end of the electric-control-box cover 2 is restricted from moving by the limit member 4, and the other end of the electric-control-box cover 2 is fixed by screws. But the present disclosure is not limited thereto, for example, the second sidewall 18 may be connected to the electric-control-box cover 2 by a buckle.

In some exemplary embodiments, as shown in FIG. 1, an air-switch module 5 is also integrated into the electric-control-box body 1. The air-switch module 5 is located on one side of the box main body 3 and connected to the box main body 3. The air-switch module 5 can perform power-off operation, implement power-off measures, and is convenient for maintenance, and the operator can operate the air-switch module 5 to perform power-off without moving during maintenance. But the present disclosure is not limited thereto, for example, the air-switch module 5 may be replaced with a junction box, which is located on one side of the box main body 3 and connected to the box main body 3 to form an integration between the junction box and the electric-control-box body 1.

As shown in FIGS. 1 to 3, the air-switch module 5 has an air switch 7 and a metal shell 6. The air switch 7 is installed within the shell 6, the shell 6 is connected to the box main body 3, and the air switch 7 is electrically connected to the electric control main board 15 through an electric wire.

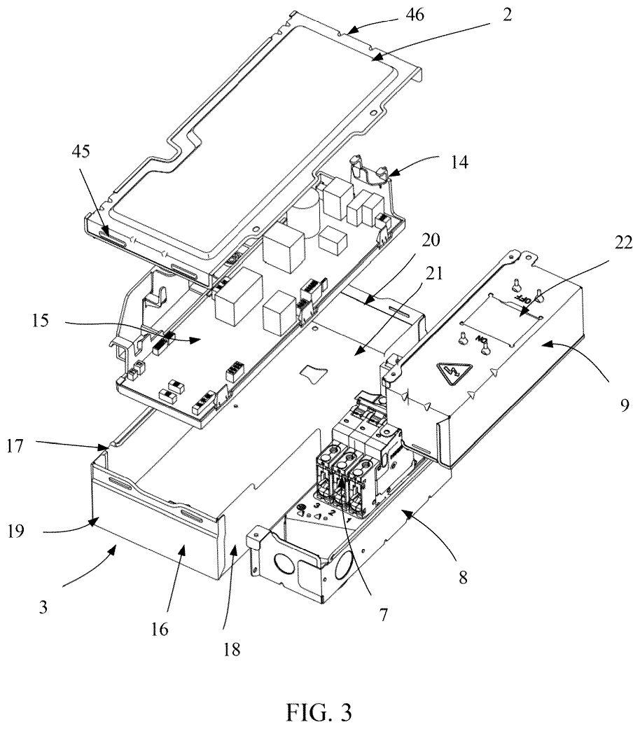

In some exemplary embodiments, as shown in FIGS. 2 and 3, the shell 6 has a mounting box 8 located on one side of the box main body 3 and a mounting cover 9. A downward side of the mounting box 8 is open, the mounting cover 9 is fixed to the bottom of the mounting box 8 by screws, the mounting cover 9 closes the open position of the mounting box 8, and the mounting box 8 and the mounting cover 9 enclose a space for mounting the air switch 7. The mounting cover 9 has a reserved opening that allows access into the shell 6, and an openable operation window 22 is provided at the position of the reserved opening, and an operation handle of the air switch 7 can be touched after the operation window 22 is manually opened. A mounting base 44 is also installed within the mounting box 8, and the air switch 7 can be fixed on the mounting base 44. Accordingly, the mounting cover 9 protects the air switch 7 alone, and even if the electric-control-box cover 2 is opened, the mounting cover 9 covers the air switch 7 to avoid the risk of electric shock.

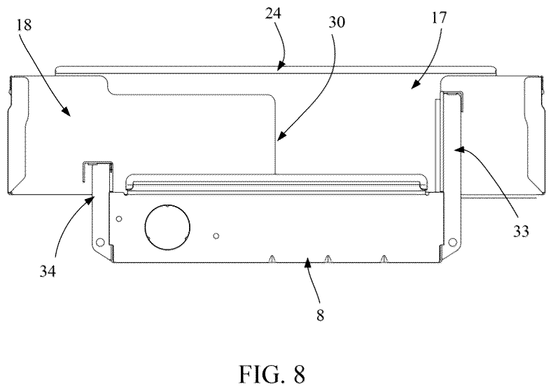

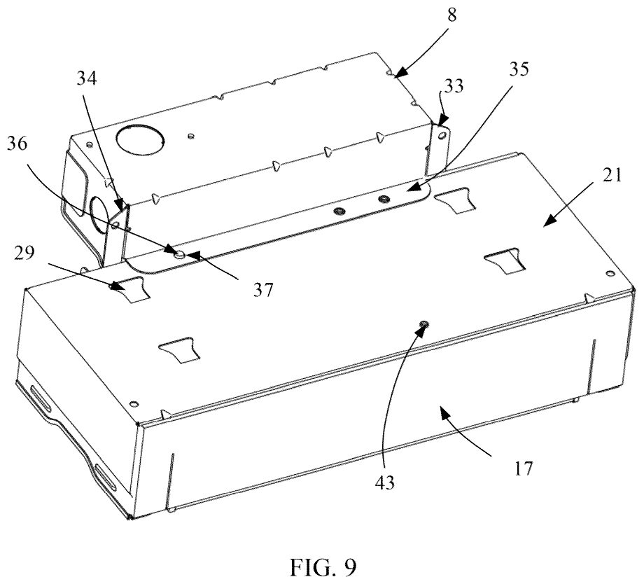

In some exemplary embodiments, the mounting box 8 is fixed to the second sidewall 18 of the box main body 3 by welding, as shown in FIGS. 8 and 9. The mounting box 8 has a first folding edge 33 and a second folding edge 34, portions of the first folding edge 33 and the second folding edge 34 fit against the second sidewall 18, and edges of the first folding edge 33 and the second folding edge 34 are welded to the second sidewall 18. In order to locate the position of the mounting box 8, an outer surface of the top plate 21 is provided with a plurality of positioning pins 36. The plurality of positioning pins 36 are close to the second sidewall 18, the positioning pins 36 are away from the first sidewall 17. A bottom edge of the mounting box 8 is provided with a hemming edge 35 at the position corresponding to the second sidewall 18, the hemming edge 35 extends horizontally and fits against a top surface of the top plate 21, and the hemming edge is provided with a plurality of positioning holes 37. The positioning pins 36 are inserted into the positioning holes 37 in one-to-one correspondence, so as to locate the position of the mounting box 8 before welding, facilitate welding and improve work efficiency. The second sidewall 18 is provided with a notch 30 at a position corresponding to the air switch 7, and the notch 30 facilitates a cable of the air-switch module 5 to penetrate into the box main body 3. The mounting box 8 is not limited to being fixed only by welding, for example, the mounting box 8 can be connected to the box main body 3 by screw connection.

In some exemplary embodiments, as shown in FIGS. 5 and 10, the bottom of the mounting box 8 is provided with two second fixation holes 31, and the two second fixation holes 31 are located on a side of the mounting box 8 close to the second sidewall 18. The mounting cover 9 is provided with two third fixation holes 38, the two third fixation holes 38 and the two second fixation holes 31 are arranged in one-to-one correspondence. The mounting box 8 and the mounting cover 9 can be connected by screws penetrating the second fixation holes 31 and the third fixation holes 38.

In some exemplary embodiments, the second edge 11 is located on a lower side of the air-switch module 5 and close to the mounting cover 9, and the bottom of the mounting cover 9 is provided with two fourth fixation holes 39 at a position close to the second sidewall 18. Correspondingly, the second edge 11 is provided with two first fixation holes 12, and the two first fixation holes 12 correspond to the two fourth fixation holes 39. The second edge 11 and the mounting cover 9 are connected by screws penetrating the second edge 11 and the mounting cover 9, so that the electric-control-box cover 2 is fixed on the mounting cover 9. Therefore, if the air-switch module 5 is to be opened, the electric-control-box cover 2 needs to be removed first, and then the mounting cover 9 can be removed. This design can improve the safety of the electric control box.

When assembling the electric control box, first, it is needed to weld the mounting box 8 to the box main body 3, and the mounting box 8 can be positioned by the cooperation between the positioning pins 36 and the positioning holes 37 before welding. Next, it is needed to install the wiring base board 14. The wiring base board 14 is buckled on the top plate 21 by using the buckles 13, and after the buckles 13 are cooperated in place with the mounting holes 29, one screw is used to penetrate through the fifth fixation hole 41 and the sixth fixation hole 43 in sequence to fasten the wiring base board 14 on the box main body 3. Then, the electric control main board 15 needs to be installed, and the electric control main board 15 is tightly buckled to the wiring base board 14 by the cooperation relationship between the limiting buckles 42 and the edge of the electric control main board 15. Subsequently, the air switch 7 and the mounting cover 9 are installed. The air switch 7 is first obliquely buckled on one side of the mounting base 44, and then the other side is pressed to be buckled in place, and then the mounting cover 9 is installed on the mounting box 8 by screws penetrating through the third fixation holes 38 and the second fixation holes 31 in sequence. Finally, the electric-control-box cover 2 is installed, it is needed to first insert the first edge 10 of the electric-control-box cover 2 into the socket 23 through the opening 47, and then align the first fixation holes 12 with the fourth fixation holes 39 and then fix them with screws, so that the assembly process of the electric control box is fully completed, and the whole process is convenient and fast. When the electric control box is required to be disassembled, a reverse operation of the above steps can be performed. The operator does not need to hold the electric-control-box cover 2 by hand when the electric-control-box cover 2 is disassembled. The operator directly screws off the screws fixing the electric-control-box cover 2, the second edge 11 is not restricted and slightly rotates downward, the socket 23 is fitted with the first edge 17. The electric-control-box cover 2 is supported by abutting a lower end face of the electric-control-box cover 2 against an end face of the support section 25 facing the box main body 3, and a part of the bottom rim 28 abuts against a part of an upper end face of the electric-control-box cover 2, so as to prevent the electric-control-box cover 2 from turning over. In this state, the first edge 10 is limited and the second edge 11 is suspended. This state is referred to as a cantilevered state, which can prevent the electric-control-box cover 2 from falling, reduce the risk of falling, and improve the safety and efficiency of installation and maintenance.

An embodiment of the present disclosure provides an air conditioner, which includes an air conditioner indoor unit, the air conditioner indoor unit is suspended on a ceiling, and the electric control box is installed in the air conditioner indoor unit.

An embodiment of the present disclosure provides an air conditioner, which includes an air conditioner indoor unit, the air conditioner indoor unit is a wall-mounted type or a cabinet type, and the electric control box is installed in the air conditioner indoor unit.

The above-described embodiments express only a few implementations of the present disclosure, and the description thereof is relatively specific and detailed, but the above-described implementations are adopted for the purpose of facilitating understanding of the present disclosure, and are not intended to limit the present disclosure. Without departing from the spirit and scope disclosed in the present disclosure, any person skilled in the art to which the present disclosure pertains may make any modifications and changes in the form and details of implementation, but the scope of patent protection of the present disclosure shall still be defined by the appended claims.

1.-17. (canceled)

18. An electric control box comprising:
an electric-control-box body including:
an opening mouth provided at a bottom of the electric-control-box body; and
a socket provided at the bottom of the electric-control-box body, an opening of the socket being configured to face an inside of the opening mouth;
an electric-control-box cover configured to cover the opening mouth, a portion of an edge of the electric-control-box cover being configured to be inserted in the socket, and an opening wall of the socket being configured to position the electric-control-box cover in a cantilevered state.

19. The electric control box of claim 18, wherein the electric-control-box body includes:
a box main body, a bottom rim of the box main body enclosing to form the opening mouth; and
a limit member, one end of the limit member being configured to be connected with the box main body, another end of the limit member protruding from the bottom rim and extending toward the inside of the opening mouth, and the limit member and the bottom rim forming the socket.

20. The electric control box of claim 19, wherein:
the limit member is provided as an integral member with the box main body;
the limit member includes an extension plate and a flange, one end of the extension plate is connected to the bottom rim, another end of the extension plate is configured to extend away from a top of the box main body and connect with the flange, and the flange is configured to extend towards the inside of the opening mouth.

21. The electric control box of claim 20, wherein the flange includes a support section and an inclined section, one end of the support section is configured to be connected to the extension plate, another end of the support section is connected to the inclined section, the support section is parallel to the bottom rim, and the inclined section is configured to be inclined toward a side away from the opening mouth.

22. The electric control box of claim 21, wherein a thickness to of the electric-control-box cover and a width ti of the socket satisfy t1≤1.2×t0.

23. The electric control box of claim 22, wherein an extension length s of the support section from the extension plate to the inclined section satisfies s≥2×t1.

24. The electric control box of claim 21, wherein an included angle θ formed between the inclined section and the supporting section is in a range of 150° to 180°.

25. The electric control box of claim 20, wherein:
the box main body includes a plurality of sidewalls connected end to end and including a first sidewall and a second sidewall arranged opposite to each other;
the limit member is arranged at one end of the first sidewall close to the opening mouth; and
the second sidewall is provided with a fixation member connected with the electric-control-box cover by a screw.

26. The electric control box of claim 19, further comprising:
a wiring base board arranged within the box main body;
wherein:
the box main body includes a top plate located on a side of the box main body away from the opening mouth;
a buckle structure is provided between the top plate and the wiring base board, and the buckle structure is configured to position the wiring base board;
the wiring base board is connected to the top plate by at least one screw.

27. The electric control box of claim 26, wherein the buckle structure includes:
a mounting hole provided on the top plate; and
a buckle provided on the wiring base board, and protruding from a top surface of the wiring base board and buckled with the mounting hole.

28. The electric control box of claim 26, wherein the buckle structure is one of at least two buckle structures provided between the top plate and the wiring base board.

29. The electric control box of claim 26, further comprising:
an electric control main board;
wherein:
the wiring base board is provided with a positioning groove, and the electric control main board is installed in the positioning groove;
the wiring base board is provided with a plurality of limiting buckles arranged along a peripheral direction of the electric control main board and buckled with an edge of the electric control main board to fix the electric control main board.

30. The electric control box of claim 26, wherein the wiring base board is provided with a reinforcement rib extending towards the opening mouth and arranged corresponding to the limit member.

31. The electric control box of claim 19, further comprising:
an air-switch module or a junction box, the air-switch module or the junction box each includes a shell configured to be connected to an outer wall of the electric-control-box body.

32. The electric control box of claim 31, wherein:
the shell includes a mounting box welded to the box main body and a mounting cover arranged on the mounting box;
the electric-control-box cover includes a first edge and a second edge arranged opposite to each other, the first edge is configured to be inserted in the socket, the second edge is arranged corresponding to the shell, and the second edge extends to a bottom surface of the mounting cover and is connected with the mounting cover by at least one screw.

33. The electric control box of claim 32, wherein:
an outer wall of the box main body is provided with a positioning pin;
an end of the mounting box connected with the mounting cover is provided with a hemming edge fitting against the outer wall of the box main body, and the hemming edge is provided with a positioning hole; and
the positioning pin is correspondingly inserted in the positioning hole to limit the mounting box.

34. The electric control box of claim 31, wherein one side of the box main body close to the shell is provided with a notch for passing wires.

35. An air conditioner comprising:
a ceiling-mounted air conditioner indoor unit; and
an electric control box arranged within the air conditioner indoor unit and including:
an electric-control-box body including:
an opening mouth provided at a bottom of the electric-control-box body; and
a socket provided at the bottom of the electric-control-box body, an opening of the socket being configured to face an inside of the opening mouth;
an electric-control-box cover configured to cover the opening mouth, a portion of an edge of the electric-control-box cover being configured to be inserted in the socket, and an opening wall of the socket being configured to position the electric-control-box cover in a cantilevered state.
